(19) United States
(12) Patent Application Publication
(10) Pub. No.: US 2014/0148014 A1
(43) Pub. Date: May 29, 2014

(54) SUBSTRATE PROCESSING APPARATUS AND SUBSTRATE PROCESSING METHOD

(71) Applicant: KOREA RESEARCH INSTITUTE OF STANDARDS AND SCIENCE, Daejeon (KR)

(72) Inventors: ShinJae You, Daejeon (KR); Jung-Hyung Kim, Daejeon (KR); Yong-Hyung Shin, Daejeon (KR); Dae-Jin Seong, Chungcheongnam-do (KR); Daewoong Kim, Gyeongsangbukdo (KR)

(73) Assignee: KOREA RESEARCH INSTITUTE OF STANDARDS AND SCIENCE, Daejeon (KR)

(21) Appl. No.: 14/082,823

(22) Filed: Nov. 18, 2013

(30) Foreign Application Priority Data
Nov. 28, 2012 (KR) 10-2012-0136023

(51) Int. Cl. H01L 21/311

(52) U.S. Cl. CPC H01L 21/31116
USPC 438/712; 156/345.35

(57) ABSTRACT

A substrate processing apparatus and method includes a chamber, a remote plasma source outside the chamber to provide activated ammonia and activated hydrogen fluoride into the chamber, and a direct plasma source to provide ion energy to a substrate inside the chamber. The plasma source includes ground electrodes extending in a first direction on a first plane perpendicularly spaced apart from a plane on which the substrate is disposed and defined by the first direction and a second direction perpendicular to the first direction and power electrodes disposed between the ground electrodes, extending in the first direction parallel to each other and receiving power from an RF power source to generate plasma between adjacent ground electrodes. The activated ammonia and the activated hydrogen fluoride are supplied on the substrate through a space between the power electrode and the ground electrode.

### CROSS-REFERENCE TO RELATED APPLICATION

This U.S. non-provisional application claims priority under 35 U.S.C. §119 to Korea Patent Application No. 10-2012-0136023 filed on Nov. 28, 2012, the entirety of which is hereby incorporated by reference.

### BACKGROUND

1. Field of the Invention

The present invention relates substrate processing apparatuses and, more particularly, to an apparatus for etching silicon oxide using plasma.

2. Description of the Related Art

Even when a silicon wafer is exposed to a small amount of oxygen during a semiconductor process, native silicon oxide (native SiOx) is produced on a surface of the silicon wafer.

Ammonia (NH₃) may react to hydrogen fluoride (HF) to produce NHxFy. The NH₃ and the HF react to silicon oxide on a semiconductor substrate to produce (NH₄)₂SiF₆. The (NH₄)₂SiF₆ of the semiconductor substrate is subjected to an annealing process to produce N₂, H₂O, and SiF₄. Thus, the (NH₄)₂SiF₆ may absorb heat and be vaporized to be removed.

A substrate processing method of performing a chemical oxide removal (hereinafter referred to as “COR”) treatment and a post heat treatment (hereinafter referred to as “PHT”) on a wafer is well known as a silicon oxide removal method. The COR treatment is a treatment where a product is produced through a chemical reaction of silicon oxide and gas molecule. The PHT is a treatment where the product produced in the wafer through the chemical reaction of the OCR treatment is removed from the wafer by heating the COR-treated wafer and thermally oxidizing and vaporizing the product. A substrate processing apparatus for performing a substrate processing method including a COR treatment and a PHT includes a chemical reaction processing unit and an annealing unit connected to the chemical reaction processing device. The chemical reaction processing unit includes a chamber and performs a COR treatment on a wafer accommodated inside the chamber. The annealing unit also includes a separate chamber and performs a PHT on a wafer accommodated inside the chamber.

In case of a COR treatment, a process of substituting silicon oxide with (NH₄)₂SiF₆ is low in efficient. A semiconductor substrate is transferred to another chamber to perform a PHT. The PHT is performed to heat the semiconductor substrate in the chamber at a temperature of 200 to 300 degrees centigrade. Accordingly, the (NH₄)₂SiF₆ on the semiconductor substrate may be decomposed to be vaporized and have an effect on another layer on the semiconductor substrate. Moreover, the PHT suffers from a disadvantage of long treatment time. As a result, a substrate processing apparatus for removing silicon oxide in a single chamber is required.

### SUMMARY

Embodiments of the present invention provide an apparatus for etching silicon oxide on a substrate without doing damage to another layer.

Embodiments of the present invention also provide a substrate processing apparatus in which a remote plasma source and a direct plasma source are configured with a single system, mutual interference is minimized, and ion bombardment energy of the direct plasma source is 1 electron volt (eV) to 20 eV.

A substrate processing apparatus according to an embodiment of the present invention may include a chamber; a remote plasma source disposed outside the chamber to provide activated ammonia and activated hydrogen fluoride into the chamber; and a direct plasma source to provide ion energy to a substrate disposed inside the chamber. The plasma source may include a plurality of ground electrodes extending in a first direction on a first plane perpendicularly spaced apart from a plane on which the substrate is disposed and defined by the first direction and a second direction perpendicular to the first direction; and a plurality of power electrodes disposed between the ground electrodes, extending in the first direction parallel to each other, and receiving power from an RF power source to generate plasma between adjacent ground electrodes. The activated ammonia and the activated hydrogen fluoride may be supplied on the substrate through a space between the power electrode and the ground electrode.

In an exemplary embodiment of the present invention, the substrate processing apparatus may further include a power distribution unit having a coaxial cable structure and distributing power to the power electrodes; and an RF power source supplying power to the power distribution unit.

In an exemplary embodiment of the present invention, the power distribution unit may include interlayer wirings connecting adjacent different layers to each other; and connection wirings connecting interlayer wirings disposed on the same layer. The number of layers of the interlayer wiring may be N that is the number of the power electrodes, and the number of layers of the connection wiring is N−1. The connection wiring may connect all interlayer wirings disposed just therebelow. The interlayer wiring may be disposed at a position to equally divide a connection wiring disposed just therebelow with one less than the number of interlayer wirings disposed just below the interlayer wiring. The number of layers of the interlayer wiring may be three or more.

In an exemplary embodiment of the present invention, the power distribution unit may have a shape of step-like tower where the same squares are densely stacked.

In an exemplary embodiment of the present invention, the ground electrodes may include a hole extending in a central axis direction; and nozzles extending in a second direction perpendicular to the first direction within the first plane and outputting a gas supplied to the hole.

In an exemplary embodiment of the present invention, a cross section vertically taken in the extending direction of the ground electrode may be circular, and a cross section vertically taken in the extending direction of the power electrode may be circular.

In an exemplary embodiment of the present invention, one end of the power electrode may be connected to the power distribution unit, and the other end of the power electrode may be combined with an insulator of ceramic material to be fixed to a sidewall of the chamber.

A substrate processing method according to an embodiment of the present invention may include supplying activated ammonia and activated hydrogen fluoride supplied from a remote plasma source disposed outside a chamber to silicon oxide disposed on a substrate disposed inside the chamber; purging the chamber with an inert gas; supplying an etching gas including at least one of an inert gas, hydrogen (H₂), oxygen (O₂), and chlorine (Cl₂) into the chamber; and supplying power to power electrodes disposed between ground electrodes disposed to cross the inside of the chamber such that plasma generated between the ground electrode and the power electrode is exposed to the substrate to remove the silicon oxide while the etching gas is supplied into the chamber.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIG. 1 illustrates a process where a remote plasma source of a substrate processing apparatus according to an embodiment of the present invention provides a radical to a chamber.

FIG. 2 illustrates that a direct plasma source of the substrate processing apparatus in FIG. 1 operates.

FIG. 3 is a cross-sectional view taken along the line I-I′ in FIG. 2.

FIG. 4 is a cross-sectional view taken along the line II-II′ in FIG. 3.

FIG. 5 illustrates a power distribution unit in FIG. 3.

FIGS. 6 and 7 illustrate a power distribution unit of a four-layer structure and a power distribution unit of a five-layer structure, respectively.

### DETAILED DESCRIPTION

A substrate processing apparatus according to an embodiment of the present invention includes a direct plasma source and a remote plasma source. A process of substituting silicon oxide with (NH₄)₂SiF₆ and a process of etching the (NH₄)₂SiF₆ are required to remove the silicon oxide. The remote plasma source is used to substitute the silicon oxide with (NH₄)₂SiF₆, and the direct plasma source is used to etch the (NH₄)₂SiF₆.

The remote plasma source generates a radical at the outside of a chamber through a plasma treatment without supplying the direct plasma source to a substrate. The generated radical is supplied to the substrate. Thus, the radical may chemically react to the silicon oxide to generate (NH₄)₂SiF₆. The remote plasma source is used to reduce active energy for the chemical reaction between the radical and the silicon oxide. Thus, the remote plasma source generates a radical such as activated ammonia (NH₃) or activated hydrogen fluoride (HF). The silicon oxide reacting to the radical is substitute with (NH₄)₂SiF₆.

The direct plasma source is used such that the (NH₄)₂SiF₆ is decomposed to be removed. The direct plasma source provides an ion having low ion energy of 1 electron volt (eV) to 20 eV to a substrate while uniformly supplying the radical supplied by the remote plasma source to the substrate. The (NH₄)₂SiF₆ may not obtain activation energy from heat energy but obtain activation energy from the ion energy to chemically react to a process gas such as oxygen. Thus, (NH₄)₂SiF₆ may chemically react to the process gas such as oxygen to be decomposed as a volatile material to be vaporized. Accordingly, there is a need for a direct plasma source that has low ion energy of 1 eV to 20 eV and may uniformly supply the radical supplied by the remote plasma source to the substrate.

A direct plasma source according to an embodiment of the present invention may have a structure where bar-shaped power electrodes receiving RF power and bar-shaped ground electrodes are arranged side by side on the same plane. A substrate may be disposed to be vertically spaced from the plane. Thus, the power electrode and the ground electrode may allow radicals to pass therethrough. An ion having high energy of 20 eV or more may not impinge on the substrate.

Exemplary embodiments of the present invention will now be described more fully with reference to the accompanying drawings, in which exemplary embodiments of the present invention are shown. Exemplary embodiments of the present invention may, however, be embodied in many different forms and should not be construed as limited to the embodiments set forth herein. Rather, these exemplary embodiments of the present invention are provided so that this description will be thorough and complete, and will fully convey the concept of exemplary embodiments of the present invention to those of ordinary skill in the art. In the drawings, the sizes and relative sizes of elements may be exaggerated for clarity. Like numerals refer to like elements throughout.

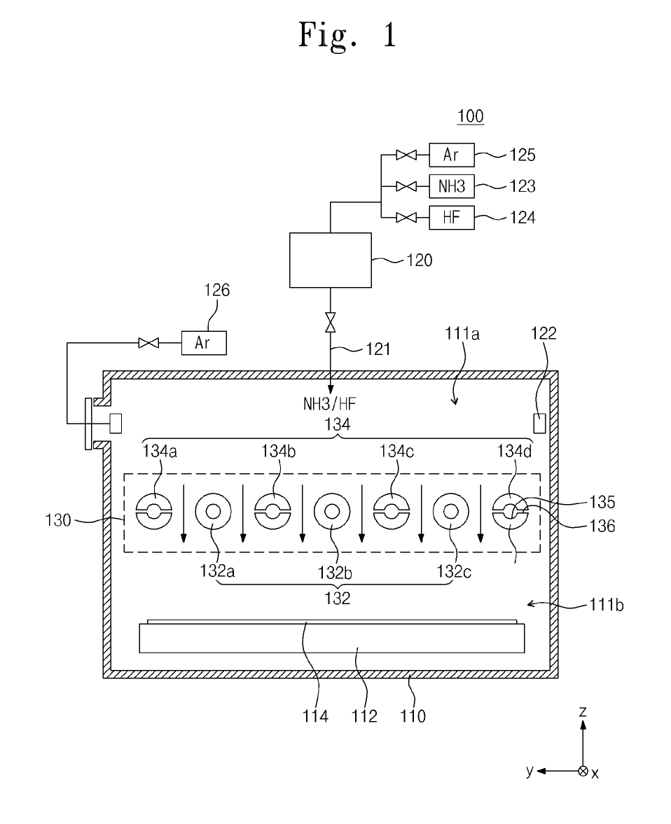

FIG. 1 illustrates a process where a remote plasma source of a substrate processing apparatus 100 according to an embodiment of the present invention provides a radical to a chamber.

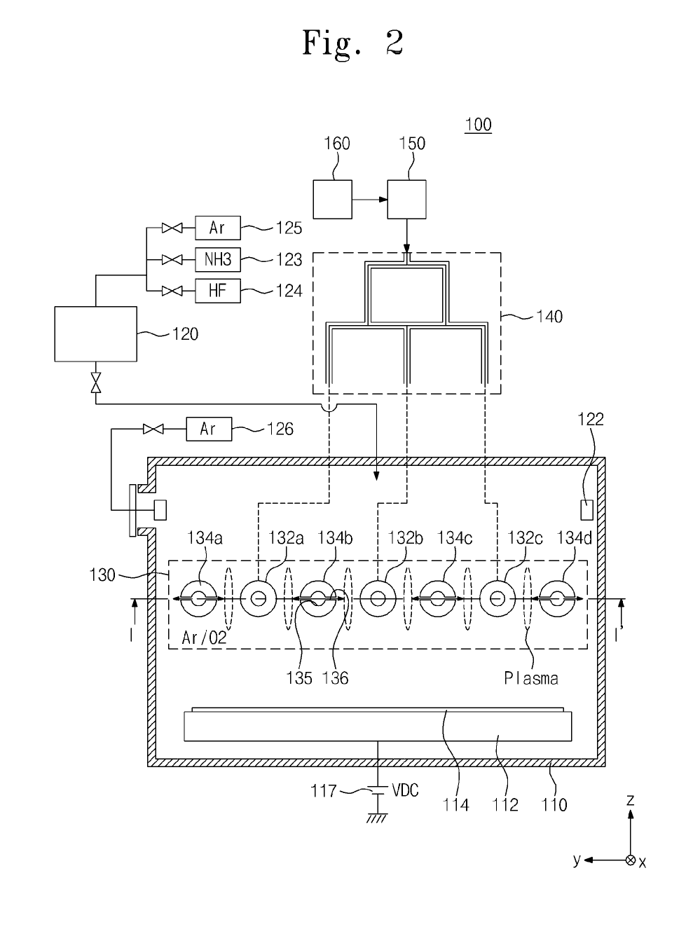

FIG. 2 illustrates that a direct plasma source of the substrate processing apparatus 100 in FIG. 1 operates.

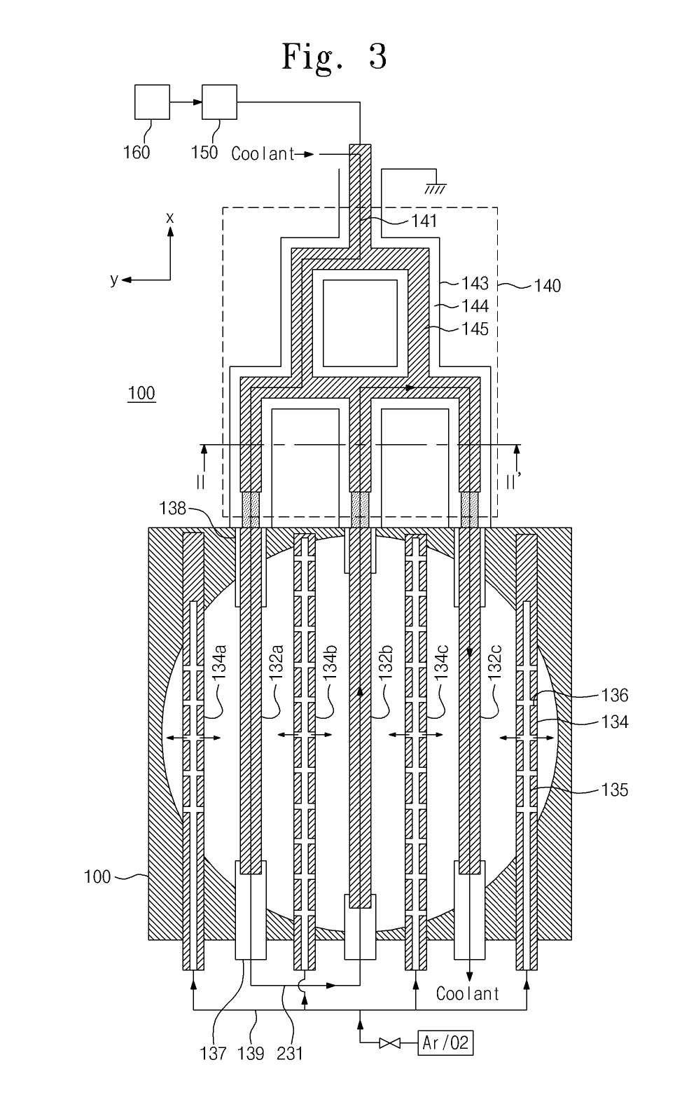

FIG. 3 is a cross-sectional view taken along the line I-I′ in FIG. 2.

Referring to FIGS. 1 to 3, the substrate processing apparatus 100 includes a chamber 110, a remote plasma source 120 disposed outside the chamber 110 to provide activated ammonia and activated hydrogen fluoride into the chamber 110, and a direct plasma source 130 to provide ion energy to a substrate 114 disposed inside the chamber 110. The direct plasma source 130 includes a plurality of ground electrodes 134 and a plurality of power electrodes 132. The ground electrodes 134 extend in a first direction α-direction) on a first plane defined by the first direction (x-direction) and a second direction (y-direction) perpendicular to the first direction (x-axis). The first plane is perpendicularly spaced apart from a plane on which the substrate 114 is disposed. The power electrodes 132 are disposed between the ground electrodes 134, extend in the first direction parallel to each other, and receive power from an RF power source 160 to generate plasma between adjacent ground electrodes. The activated ammonia and the activated hydrogen fluoride are supplied on the substrate 114 through a space between the power electrode 132 and the ground electrode 134.

The inside of the chamber 110 may have a cylindrical structure, and the outside thereof may have a square-tube structure. The chamber 110 may be divided into an upper region 111a and a lower region 111b on the basis of a region in which the direct plasma source 130 is disposed. The chamber 110 may be made of a conductive material, and a substrate holder 112 may be disposed in the lower region 111b. The substrate 114 may be disposed on the substrate holder 112. The substrate 114 may include silicon oxide. The chamber 110 may include a pumping port (not shown) and may be exhausted through the pumping port.

The remote plasma source 120 may perform discharge by receiving an ammonia gas and a hydrogen fluoride gas from an ammonia gas storage 123 and a hydrogen fluoride gas storage 124. The remote plasma source 120 may further receive an inert gas from an inert gas storage 125 other than ammonia (NH₃) and hydrogen fluoride (HF).

The remote plasma source 120 may be disposed outside the chamber 120, and the activated ammonia (NH₃) and the activated hydrogen fluoride (HF) generated by the remote plasma source 120 may be supplied to the center of the upper region 111a of the chamber 110 through a gas line 121. A radical gas distribution unit (not shown) may be disposed in the upper region 111a of the chamber 110 to spatially distribute a radial that the remote plasma source 120 supplies. The remote plasma source 120 may perform discharge by receiving NH3 and HF to activate a process gas supplied to the remote plasma source 120. The activated process gas may include ammonia (NH₃) and hydrogen fluoride (HF). For effective discharge, the activated process gas may further include an inert gas of about 10 percent to about 99 percent. A flow rate of the process gas may be about 10 sccm to about 60 sccm. When the remote plasma source 120 supplies activated ammonia and activated hydrogen fluoride into the chamber 110, the chamber 110 may be maintained at a process pressure of several milliTorr (mTorr) to tens of milliTorr (mTorr).

The activated ammonia (NH₃) and the activated hydrogen fluoride (HF) may react to silicon oxide to create (NH₄)₂SiF₆. That is, the silicon oxide is substituted with (NH₄)₂SiF₆. A temperature of the substrate 114 may be a room temperature during the substitution process.

A purge gas distribution ring 122 may be disposed on an inner side surface of the upper region 111a of the chamber 110. The purge gas distribution ring 122 may have a ring shape and include nozzles arranged at regular intervals.

An inert gas may be supplied into the chamber 110 through the purge gas distribution ring 122 after the substitution process of the silicon oxide. Thus, a purge process may be performed to remove the activated ammonia (NH₃) and the activated hydrogen fluoride (HF) that remain inside the chamber 110.

The direct plasma source 130 removes the substituted (NH₄)₂SiF₆ by decomposing the same. The direct plasma source 130 removes the (NH₄)₂SiF₆ by decomposing the same into volatile gases (N₂, H₂O, SiF₄, CO₂, and NH₃). In this case, a temperature of the substrate 114 may be a room temperature of about 25 degrees centigrade. A method using the direct plasma source 130 may reduce a thermal damage to the substrate 114, as compared to a conventional thermal method (200 degrees centigrade).

The direct plasma source 130 may generate plasma having ion energy of about 1 eV to 20 eV to effectively decompose and remove (NH₄)₂SiF₆ during a dry etch and minimize an influence on another layer on the substrate 114.

Activation energy for decomposing (NH₄)₂SiF₆ may be greater than 1 eV. On the other hand, activation energy for removing silicon oxide through physical sputtering may be greater than about 20 eV. Accordingly, a direct plasma source according to an embodiment of the present invention may provide plasma having ion bombardment energy of 1 eV to 20 eV. The direct plasma source may have an electrode structure where power electrodes are disposed between ground electrodes.

Conventionally, a plate-type capacitively coupled plasma source includes an upper electrode to which power is supplied and a substrate holder disposed opposite to the upper electrode. The substrate holder and a chamber wall may be grounded. The plate-type capacitively coupled plasma source may generate high energy above 20 eV to damage a substrate.

Oxygen plasma (O₂ plasma) may be used to decompose (NH₄)₂SiF₆ into a nonvolatile material. The oxygen plasma may activate oxygen atoms and oxygen molecules by decomposing an oxygen gas. The ion energy of plasma may further receive activation energy of chemical reaction of the (NH₄)₂SiF₆. Thus, the substrate 114 may be maintained at room temperature with the help of the oxygen plasma and the (NH₄)₂SiF₆ may be removed. A voltage of the substrate holder 112 may be changed to a predetermined positive voltage through a DC power source 117 while the direct plasma source operates. Accordingly, a potential difference between the plasma potential and a potential of the substrate holder 112 may be reduced. Thus the energy of ions impinging on the substrate 114 may be controlled. The substrate damage can be reduced.

The direct plasma source 130 may perform discharge using process gases (O₂, H₂, and Cl₂) and an inert gas. A pressure of the chamber 110 may be tens of milliTorr (mTorr) to hundreds of milliTorr (mTorr) while the direct plasma source 130 operates.

After the direct plasma source 130 performs an etch process of (NH₄)₂SiF₆, the chamber 110 may be re-purged with an inert gas supplied from the purge gas distribution ring 122.

In an embodiment of the present invention, a structure including a power electrode 132 disposed between a plurality of bar-shaped ground electrodes 134 may reduce ion energy. Thus, substrate damage caused by plasma may be reduced. In addition, ion bombardment energy of ions accelerated around the power electrodes 132 to reach the substrate 114 may range from 1 eV to 20 eV. In particular, a direction of an electric field between a ground electrode and a power electrode may be mainly present on a first plane. Accordingly, a direction of accelerated ions and a direction of electrons are mainly present on the first plane. Accordingly, the energy of ions impinging on a substrate perpendicularly spaced apart from the first plane rarely has a z-axis component. As a result, the energy of ions impinging on the substrate is given by a potential difference caused by a sheath. On the other hand, the potential difference in the sheath may be adjusted through the DC power source 117.

The plasma source 130 includes ground electrodes 134 and power electrodes 132 disposed between the ground electrodes 134.

The ground electrode 134 is disposed to extend in a first direction α-axis direction) on a plane perpendicularly spaced apart from the plane on which the substrate 114 is disposed. A distance between adjacent ground electrodes may be constant. The ground electrode 134 may have a cylindrical shape, and the inside of the ground electrode 134 may include a hole 135 extending in the first direction. A nozzle 136 may be connected to the hole 135 and may extend in a second positive direction and a second negative direction that are perpendicular to the first direction and are located on the first plane. The nozzle 136 may be periodically arranged in the first direction.

The ground electrodes 134 include a hole 135 extending in a central axis direction and nozzles 136 extending in a second direction perpendicular to the first direction within the first plane and outputting a gas supplied to the hole 135.

The exposed length of the ground electrode 134 may vary depending on a location of the ground electrode 134. Specifically, four ground electrodes 134 may be disposed across the chamber 110 and length of two ground electrodes 134b and 134c disposed in the center of the chamber 110 may be substantially equal to an inner diameter of the chamber 110. The length of ground electrodes 134a and 13d disposed at the edge of the chamber 110 may be smaller than the length of the two ground electrodes 134b and 134c disposed in the center of the chamber 110.

Both ends of the ground electrode 134 may be inserted into a groove formed on a side surface of the chamber 110. A gas supply line 139 may be connected to the hole 135 of the ground electrode 134. Thus, a supplied etching gas may be outputted to the power electrode through the hole 135 and the nozzle 136. An etching gas supplied through the ground electrode 134 may include inert gases (Ar, He, Ne, and Xe) and process gases (H₂, O₂, and Cl₂). A cross section vertically taken in the extending direction of the ground electrode 134 may be circular.

The power electrodes 132 may be disposed between the ground electrodes 134 and extend parallel to each other in the first direction. The power electrodes 132 may receive power from an RF power source 160 to generate plasma between adjacent ground electrodes 134. The length of the power electrode 132 may vary depending on its location. The exposed length of a power electrode 132b crossing the center of the chamber 110 may be greater than the length of power electrodes 132a and 132c spaced apart from the center of the chamber 110 to cross the chamber 110 camber 110. A distance between the power electrodes 132 may be constant. Accordingly, a vertical distance between the power electrode 132 and the ground electrode 134 may be constant.

The power electrodes 132 may extend parallel to each other in the first direction. Each of the power electrodes 132 may have a cylindrical shape. One end of the power electrode 132 may be connected to the power distribution unit 140 through connection means 242, and the other end of the power electrode 132 may be combined with an insulator 137 of a ceramic material to be fixed to a sidewall of the chamber 110. The insulator 137 may be inserted into a groove formed on the side surface of the chamber 110 to be fixed thereto. The other ends of the insulator 137 and the power electrodes 132 may be bonded using a brazing technique. Thus, discharge may be suppressed between the other end of the power electrode 132 and the sidewall of the chamber 110. A cross section taken vertically in the extending direction of the power electrode 132 may be circular.

The insulator 137 includes a through-hole therein, and a coolant may flow into the through-hole. A ceramic pipe 138 may be inserted into one end of the power electrode 132. The ceramic pipe 138 may be inserted into a groove formed at the chamber 110 to suppress discharge between the power electrode 132 and the side surface of the chamber 110.

A fluid path extending in the first direction may be formed in the power electrode 132. The coolant may flow through the fluid path. Coolants flowing through adjacent power electrodes may be serially connected to each other. A coolant flowing through the power electrode 132 may be exhausted to the outside of the chamber 110.

A frequency of the RF power source 160 may be several megahertz (MHz) to hundreds of megahertz (MHz). An output of the RF power source 150 is provided to the power distribution unit 140 through an impedance matching network 150.

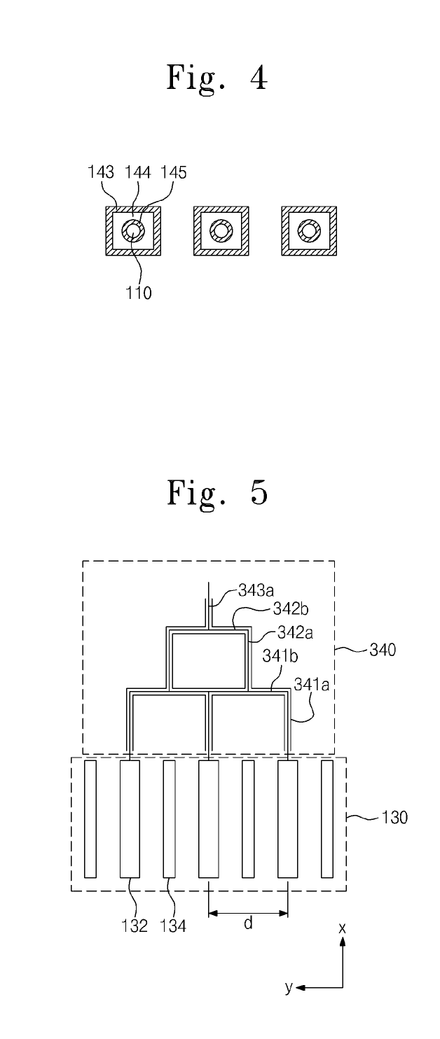

FIG. 4 is a cross-sectional view taken along the line II-II′ in FIG. 3.

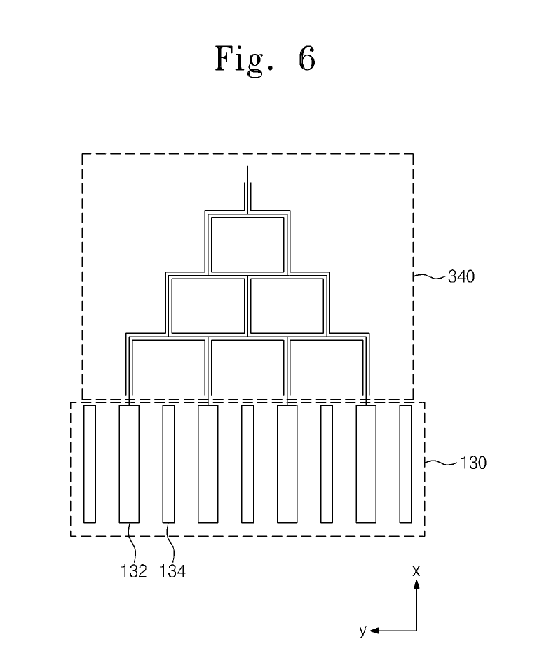

FIG. 5 illustrates the power distribution unit 140 in FIG. 3.

Referring to FIGS. 3 to 5, a power distribution unit 140 may have a coaxial cable structure. The power distribution unit 130 may include an inner conductive line 145, a dielectric layer 144 surrounding the inner conductive liner 145, and an outer cover conductive layer 13 surrounding the dielectric layer 144. The inner conductive layer 145 may have a shape of circular pipe, and the outer cover conductive line 13 may have a shape of square pipe.

The power distribution unit 139 may distribute power to the power electrodes 132. The power electrodes 132 may be connected in parallel to an RF power source 160. The RF power source 160 may supply RF power to the power distribution unit 140.

The power distribution unit 340 may include interlayer wirings 341a and 342a connecting adjacent different layers to each other and connecting wirings 341b and 342b connecting interlayer wirings 341a and 342a disposed on the same layer. The number of layers of interlayer wirings 341a and 342a is N that is the number of power electrodes, and the number of layers of the connection wirings 341b and 342b is N−1. The connection wirings 341b and 342b connects all interlayer wirings disposed just therebelow. The interlayer wirings 341a and 342a are disposed at a position to equally divide a connection wiring disposed just therebelow with one less than the number of interlayer wirings disposed just therebelow. The number of layers of the interlayer wirings 341a and 342a may be three or more. Lowermost interlayer wirings 341a are connected to the power electrodes 132, respectively.

A distance (d) between the adjacent power electrodes may be obtained by dividing a half wavelength (λ/2) of the RF power source 160 by the number (N) of power electrodes (i.e., d=λ/(2N)).

The power distribution unit 340 may include interlayer wirings 341a, 342a, and 343a connecting adjust different layers to each other and connection wirings 341b and 342b connecting interlayer wirings disposed on the same layer. Lowermost interlayer wirings 341a may be connected one-to-one to the power electrodes 132. The interlayer wirings may extend in the same direction, and the connection wirings may extend in a direction perpendicular to the interlayer wirings.

The number of layers of the interlayer wirings 341a, 342a, and 343a may be N that is the number of the power electrodes, and the number of the connection wirings 341b and 342b may be N−1. The connection wirings 341b may connect all interlayer wirings 341a disposed just therebelow. The interlayer wiring 342a may be disposed at a position to equally divide a connection wiring 341b disposed just therebelow with one less than the number of interlayer wirings 341a disposed below the interlayer wiring 341b.

The first interlayer wiring 341a may be connected one-to-one to the power electrode 132 with the same length. The first connection wiring 341b may linearly connect all the first interlayer wirings 341a. The second interlayer wiring 342a may divide the first connection wiring 341b into two equal parts and may be disposed in the center of the respective divided parts. The second connection wiring 342b may linearly connect the interlayer wiring 342a. The third interlayer wiring 343a may be connected to the center of the second connection wiring 342b.

The power distribution unit 340 may have a shape of step-like tower where the same squares are densely stacked. The power distribution unit 340 includes an inner conductive line and an external conductive line. The outer conductive line at the end of the power distribution unit 340 is connected to the chamber 110, and the inner conductive line at the end of the power distribution unit 340 is connected to the power electrode 132. The inner conductive line may have a pipe shape, and a coolant may flow to the inside of the inner conductive line.

A coolant is supplied through an uppermost interlayer wiring to refrigerate the power distribution unit 130. The coolant may be supplied to a power electrode through an underlying connection wiring and an underlying interlayer wiring. The coolant supplied to the power electrode may be exhausted to the outside after sequentially passing through all power electrodes. A coolant passing through some of power electrodes may be re-supplied to the power distribution unit 130. The re-supplied coolant may be supplied to another power electrode after passing through a portion of the power distribution unit 130.

A substrate processing method according to an embodiment of the present invention includes supplying activated ammonia and activated hydrogen fluoride supplied from a remote plasma source disposed outside a chamber to silicon oxide disposed on a substrate disposed inside the chamber; purging the chamber with an inert gas; supplying an etching gas including at least one of an inert gas, hydrogen (H₂), oxygen (O₂), and chlorine (Cl₂) into the chamber; and supplying power to power electrodes disposed between ground electrodes disposed to cross the inside of the chamber such that plasma generated between the ground electrode and the power electrode is exposed to the substrate to remove the silicon oxide while the etching gas is supplied into the chamber.

A film where silicon oxide is substituted with (NH₄)₂SiF₆ by a remote plasma source is finite in thickness. Accordingly, when the above process is repeated, an etch rate of the silicon oxide may be 5 nanometers per minute (nm/min) to 100 nm/min.

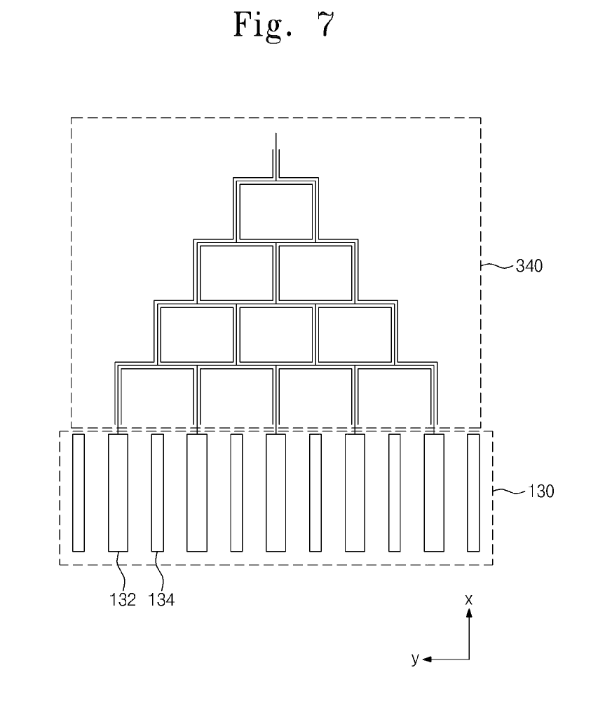

FIGS. 6 and 7 illustrate a power distribution unit of a four-layer structure and a power distribution unit of a five-layer structure, respectively.

Referring to FIGS. 6 and 7, a power distribution unit 340 may include interlayer wirings connecting adjacent different layers to each other and connection wirings connecting interlayer wirings dispose on the same layer. The number of layers of the interlayer wirings is N that is the number of power electrodes, and the number of layers of the connection wirings is N−1. The connection wiring connects all interlayer wirings disposed just therebelow. The interlayer wiring is disposed at a position to equally divide a connection wiring disposed just therebelow with one less than the number of interlayer wirings disposed just below the interlayer wiring. The number of layers of the interlayer wiring may be three or more. Lowermost interlayer wirings are connected to power electrodes 132, respectively.

As described so far, a substrate processing apparatus according to an embodiment of the present invention sequentially applies a remote plasma source and a direct plasma source to silicon oxide to reduce process time and effectively remove the silicon oxide.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A substrate processing apparatus comprising:
a chamber;
a remote plasma source disposed outside the chamber to provide activated ammonia and activated hydrogen fluoride into the chamber; and
a direct plasma source to provide ion energy to a substrate disposed inside the chamber,
wherein the plasma source comprises:
a plurality of ground electrodes extending in a first direction on a first plane perpendicularly spaced apart from a plane on which the substrate is disposed and defined by the first direction and a second direction perpendicular to the first direction; and
a plurality of power electrodes disposed between the ground electrodes, extending in the first direction parallel to each other, and receiving power from an RF power source to generate plasma between adjacent ground electrodes, and
wherein the activated ammonia and the activated hydrogen fluoride are supplied on the substrate through a space between the power electrode and the ground electrode.

2. The substrate processing apparatus of claim 1, further comprising:
a power distribution unit having a coaxial cable structure and distributing power to the power electrodes; and
an RF power source supplying power to the power distribution unit.

3. The substrate processing apparatus of claim 2, wherein the power distribution unit comprises:
interlayer wirings connecting adjacent different layers to each other; and
connection wirings connecting interlayer wirings disposed on the same layer,
wherein the number of layers of the interlayer wiring is N being the number of the power electrodes,
wherein the number of layers of the connection wiring is N-1,
wherein the connection wiring connects all interlayer wirings disposed just therebelow,
wherein the interlayer wiring is disposed at a position to equally divide a connection wiring disposed just therebelow with one less than the number of interlayer wirings disposed just below the interlayer wiring, and
wherein the number of layers of the interlayer wiring is three or more.

4. The substrate processing apparatus of claim 2, wherein the power distribution unit has a shape of step-like tower where the same squares are densely stacked.

5. The substrate processing apparatus of claim 1, wherein the ground electrodes comprise:
a hole extending in a central axis direction; and
nozzles extending in a second direction perpendicular to the first direction within the first plane and outputting a gas supplied to the hole.

6. The substrate processing apparatus of claim 1, wherein a cross section vertically taken in the extending direction of the ground electrode is circular, and
wherein a cross section vertically taken in the extending direction of the power electrode is circular.

7. The substrate processing apparatus of claim 1, wherein one end of the power electrode is connected to the power distribution unit, and the other end of the power electrode is combined with an insulator of ceramic material to be fixed to a sidewall of the chamber.

8. A substrate processing method comprising:
supplying activated ammonia and activated hydrogen fluoride supplied from a remote plasma source disposed outside a chamber to silicon oxide disposed on a substrate disposed inside the chamber;
purging the chamber with an inert gas;
supplying an etching gas including at least one of an inert gas, hydrogen (H₂), oxygen (O₂), and chlorine (Cl₂) into the chamber; and
supplying power to power electrodes disposed between ground electrodes disposed to cross the inside of the chamber such that plasma generated between the ground electrode and the power electrode is exposed to the substrate to remove the silicon oxide while the etching gas is supplied into the chamber.
